(19) United States
(12) Patent Application Publication
(10) Pub. No.: US 2024/0124967 A1
(43) Pub. Date: Apr. 18, 2024

(54) METHOD OF FORMING PLASMA-RESISTANT COATING FILM

(71) Applicant: KoMiCo Ltd., Anseong-si (KR)

(72) Inventors: Ki Seong Lim, Anseong si (KR); Joo Jin, Anseong si (KR)

(21) Appl. No.: 18/468,805

(22) Filed: Sep. 18, 2023

(30) Foreign Application Priority Data
Oct. 13, 2022 (KR) 10-2022-0131973

(51) Int. Cl. C23C 14/08; C23C 14/02

(52) U.S. Cl. CPC C23C 14/088; C23C 14/024

(57) ABSTRACT

Proposed is a method of forming a plasma-resistant coating film. The method includes (a) forming a lower coating layer on a target object by depositing a first rare-earth metal compound powder through a physical vapor deposition (PVD) process, (b) transferring a second rare-earth metal compound powder, and (c) forming an upper coating layer by spraying the transferred second rare-earth metal compound powder onto the lower coating layer, thereby obtaining a plasma-resistant coating film with fewer structural defects and enhanced physical properties.

### CROSS REFERENCE TO RELATED APPLICATION

The present application claims priority to Korean Patent Application No. 10-2022-0131973, filed Oct. 13, 2022, the entire contents of which is incorporated herein for all purposes by this reference.

### BACKGROUND OF THE DISCLOSURE

### 1. Field of the Disclosure

The present disclosure relates to a method of forming a plasma-resistant coating film. More particularly, the present disclosure relates to a method of forming a plasma-resistant coating film applied to a semiconductor manufacturing process involving semiconductor etching equipment, and to a plasma-resistant coating film.

### 2. Description of the Related Art

Next-generation semiconductors are evolving toward being light, thin, short, and small in overall dimension. In addition, with the mobile era, ultra-fine semiconductor processes are inevitably required to be used in smaller and more complex electronic devices.

In particular, difficulties in etching processes required for manufacturing semiconductor devices of nm or smaller, 3D NAND flash, FintiET, MRAM, and the like are gradually increasing, so technology for such fine pattern etching and the like is being actively developed for this purpose.

Accordingly, the importance of etching technology development of new materials and etching technology capable of selectively etching only necessary materials is likely to grow. To this end, durable semiconductor parts that enable etching equipment to withstand extreme environments are inevitably in need.

In other words, in response to ultra-fine line width processes, high-density coating is required on semiconductor parts to prevent contamination from occurring during high-power plasma (>10 Kw) processes.

Typically, chambers used for semiconductor manufacturing process facilities are formed using ceramic bulks such as an anodized aluminum alloy or alumina for insulation.

Recently, there has been a growing need for corrosion resistance to highly corrosive gases and plasmas. Accordingly, chambers used for semiconductor manufacturing processes, involving deposition facilities using chemical vapor deposition (CVD) or etching facilities using plasma etching, are being formed using methods of plasma-spraying or thermal-spraying a ceramic coating layer, such as alumina, onto the aluminum alloy.

In addition, most of the semiconductor manufacturing processes performed in chambers involve high-temperature processes such as heat treatment, chemical vapor deposition (CVD), and the like, so the chambers are required to be heat-resistant as well. Furthermore, not only parts of semiconductor manufacturing equipment, such as chambers, need to be insulative, heat-resistant, corrosion-resistant, and plasma-resistant, but also the bonding strength between a coating layer and a substrate is required to be maintained strong so that the coating layer is kept from delamination, thereby minimizing particle generation during the manufacturing process and wafer contamination caused by the generated particles.

For this reason, commonly used chemical vapor deposition (CVD), physical vapor deposition (PVD), sputtering, and the like have been conventionally applied. However, these methods are related to thin film formation processes. Therefore, there is a problem in that a process takes an excessively long time to form a thick film that satisfies the requirements such as corrosion resistance and the like, resulting in a decrease in economic feasibility. In addition, it is problematic that strong bonding strength between a substrate and a coating layer is difficult to be obtained.

On the other hand, aerosol deposition (AD) is a method of spraying an aerosol containing ceramic particles from a nozzle onto a base material, causing the particles to collide with the base material, and using the collision force to form a ceramic coating film on the base material. Since the powder to be applied is directly sprayed, high-speed coating at a speed of about 30 μm per minute is enabled, and thickness control is enabled due to the proportional recovery.

However, aerosol deposition (AD) may cause problems such as delamination when used for a long time due to low adhesive strength formed by simply mechanical engagement between the coating film and the surface of the base material. In addition, the film may be etched by CF4 plasma ions and radicals used for a thy-etching process, thereby generating particles and contaminating the wafer.

Hereinafter, existing technology in the art to which the present disclosure belongs will be briefly described. Then, the technical details to be distinctively achieved by the present disclosure will be described.

Korean Patent Application Publication No. 10-2013-0123821 (filed Nov. 13, 2013) relates to a plasma-resistant coating film. Disclosed is a technology for forming the plasma-resistant coating film. The technology includes: forming a first amorphous coating film formed by applying spray coating powder in which 30 to 50 wt % of aluminum oxide and 50 to 70 wt % of yttrium oxide are mixed on a to-be-coated target requiring plasma resistance through plasma spray coating; and forming a second coating film on the first coating film by aerosol deposition, the second coating film having higher density and better plasma resistance than the first coating film, thereby providing plasma resistance, a high withstand voltage level, and high electrical resistance.

In addition, Korean Patent Application Publication No. 10-2017-0080123 (filed Jul. 10, 2017) relates to a plasma-resistant coating film and specifically to a technology for forming a plasma-resistant coating film. In the technology, not only the chemical resistance is obtainable by minimizing open channels and open pores of a coating layer through double sealing with aerosol deposition and hydration treatment, after spray-coating of a first rare-earth metal compound, but also plasma corrosion resistance is obtainable due to a dense rare-earth metal compound coating film.

However, in the plasma-resistant coating films containing multilayer-structured coating layers prepared according to the documents of the related art, problems of particle generation and delamination resulting from a decrease in bonding strength between the coating layers still remain. As a result, there is a need for technology for forming a plasma-resistant coating film with durability and a long life span.

Therefore, the inventors of the present disclosure recognized limitations in such formation methods of plasma-resistant coating films. As a result of repeatedly conducting research on a formation method in which a thin film has excellent plasma resistance while bonding strength between coating layers is optimized, the present disclosure has been completed.

### Documents of Related Art

### Patent Document

Patent Document 001: Korean Patent Application Publication No. 10-2013-0123821 (publication date: Nov. 13, 2013)
Patent Document 002: Korean Patent Application Publication No. 10-2017-0080123 (publication date: Jul. 10, 2017)

### SUMMARY OF THE INVENTION

One of the main objectives of the present disclosure is to provide a method of forming a plasma-resistant coating film in which the bonding strength of the coating film is excellent while preventing formation of structural defects in the coating film, thereby minimizing particle generation or delamination of the coating film that may occur during a semiconductor manufacturing process.

In addition, another objective of the present disclosure is to provide a plasma-resistant member on which the plasma-resistant coating film is formed, using the method of forming the plasma-resistant coating film.

To achieve the above objectives, one embodiment of the present disclosure provides a method of forming a plasma-resistant coating film. The method is characterized by including (a) forming a lower coating layer on a target object by depositing a first rare-earth metal compound powder through a physical vapor deposition (PVD) process, (b) transferring a second rare-earth metal compound powder, and (c) forming an upper coating layer by spraying the transferred second rare-earth metal compound powder onto the lower coating layer formed in the (a) forming.

In one preferred embodiment of the present disclosure, the first rare-earth metal compound powder has the same components as the second rare-earth metal compound powder.

In one preferred embodiment of the present disclosure, each of the first rare-earth metal compound powder and the second rare-earth metal compound powder is selected from the group consisting of yttria (Y2O3), yttrium fluoride (YF), yttrium oxyfluoride (YOF), and yttrium aluminum garnet (YAG).

In one preferred embodiment of the present disclosure, the physical vapor deposition (PVD) process is one selected from among thermal deposition, electron beam evaporation, and sputtering.

In one preferred embodiment of the present disclosure, the lower coating layer has a thickness in a range of 0.1 to 10 μm.

In one preferred embodiment of the present disclosure, the second rare-earth metal compound powder has a median diameter (D50) in a range of 0.1 to 10 μm.

In one preferred embodiment of the present disclosure, the upper coating layer has a thickness in a range of 1 to 30 μm.

In another preferred embodiment of the present disclosure, the present disclosure provides a plasma-resistant coating film formed by the method of forming the plasma-resistant coating film described above.

In a method of manufacturing a plasma-resistant coating film according to the present disclosure, a first rare-earth metal compound is applied to a lower coating layer through physical vapor deposition (PVD). As a result, when spraying a second rare-earth metal compound powder to form an upper coating layer, the lower coating layer can receive the impact applied to a target object from the second rare-earth metal compound powder. Therefore, the occurrence of structural defects that may occur in the upper coating layer containing the second rare-earth metal compound can be minimized.

In addition, in the plasma-resistant coating film formed according to the present disclosure, the structural defects in the coating film can be minimized, thereby reducing the porosity that may result from the structural defects. Furthermore, the coating film can exhibit enhanced physical properties.

### BRIEF DESCRIPTION OF THE DRAWINGS

FIG. 1 is a schematic diagram illustrating energy conversion occurring when forming a rare-earth metal compound coating layer by spraying a rare-earth compound powder onto a target object;

FIG. 2 shows scanning electron microscope (SEM) images for the side of a coating film prepared according to Comparative Example 1; and

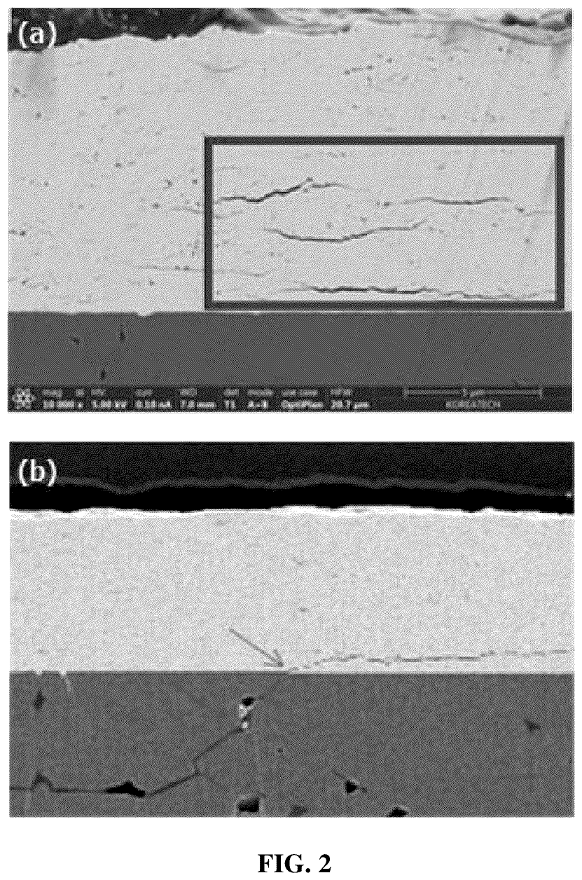

FIG. 3 shows an SEM image for the side of a coating film prepared according to Example 1.

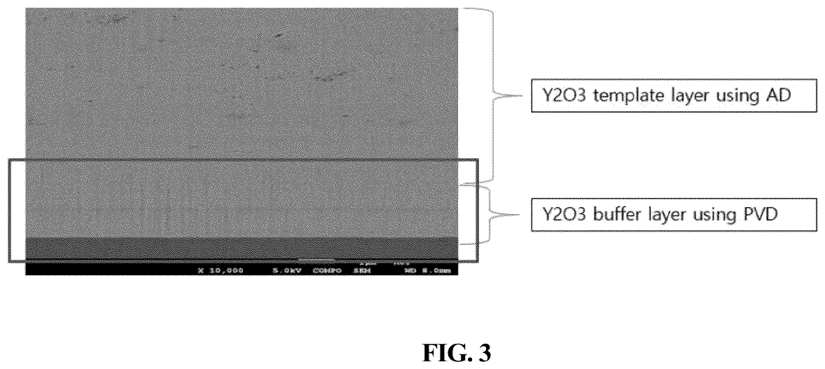

### DESCRIPTION OF EXEMPLARY EMBODIMENTS

Unless defined otherwise, all terms including technical and scientific terms used herein have the same meaning as commonly understood by those skilled in the art to which the present disclosure belongs. Typically, the nomenclature used herein is well-known and commonly used in the art.

It will be further understood that the terms “comprise”, “include”, “have”, etc. when used in this specification, specify the presence of stated features, integers, steps, operations, elements, components, and/or combinations thereof, but do not preclude the presence or addition of one or more other features, integers, steps, operations, elements, components, and/or combinations thereof.

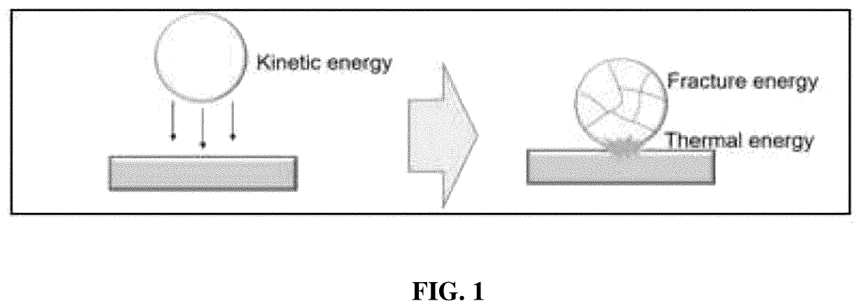

FIG. 1 is a schematic diagram illustrating energy conversion occurring when forming a rare-earth metal compound coating layer by spraying a rare-earth compound powder onto a target object.

As illustrated in FIG. 1, when forming the rare-earth metal compound coating layer by spraying the rare-earth compound powder onto the target object, the kinetic energy of the rare-earth compound powder is converted into thermal energy and fracture energy, causing structural defects such as cracks in the target object and the coating layer.

To overcome such problems, the present disclosure provides a method of forming a plasma-resistant coating film capable of exhibiting enhanced physical strength of the coating film and reducing the porosity of the coating film by minimizing structural defects occurring in a rare-earth metal compound coating layer.

In one aspect of the present disclosure, the method of forming the plasma-resistant coating film includes (a) forming a lower coating layer on a target object by depositing a first rare-earth metal compound powder through a physical vapor deposition (PVD) process, (b) transferring a second rare-earth metal compound powder, and (c) forming an upper coating layer by spraying the transferred second rare-earth metal compound powder onto the lower coating layer formed in the (a) forming. In this case, the first rare-earth metal compound powder has the same components as the second rare-earth metal compound powder.

First, in the method of forming the plasma-resistant coating film according to the present disclosure, the lower coating layer is formed on the target object by depositing the first rare-earth metal compound powder through the physical vapor deposition (PVD) process [(a)].

The target object on which the lower coating layer containing the first rare-earth metal compound is formed may be parts of plasma devices, such as an electrostatic chuck applied to the inside of a plasma device, a heater, a chamber liner, a shower head, a CVD boat, a focus ring, a wall liner, and the like. In addition, the target object may be made of: metal, including iron, magnesium, aluminum, and alloys thereof; ceramic materials, including SiO2, MgO, CaCO3, and alumina; and polymeric materials, including polyethylene terephthalate, polyethylene naphthalate, polypropylene adipate, and polyisocyanate. However, the materials of the target object are not limited thereto.

The first rare-earth metal compound may include yttria (Y2O3), yttrium fluoride (YF), yttrium oxyfluoride (YOF), yttrium aluminum garnet (YAG), or a mixture thereof. Specifically, the first rare-earth metal compound is preferably yttria (Y2O3).

The first rare-earth metal compound constituting the lower coating layer is highly resistant to plasma exposed during the semiconductor process. Therefore, when being applied to semiconductor equipment parts required to be corrosion-resistant, such as semiconductor etching equipment, corrosion resistance to the plasma of the semiconductor process and a withstand voltage level may be obtained.

In the formation of the lower coating layer on the target object, any physical vapor deposition (PVD) capable of forming a coating layer that satisfies the requirements, including strong bonding strength between the target object and the coating layer, corrosion resistance, and the like, is applicable without limitation. Specifically, the physical vapor deposition (PVD) may be one selected from among thermal deposition, electron beam evaporation, and sputtering, and is preferably electron beam evaporation.

In the (a) forming, the lower coating layer containing the first rare-earth metal compound is formed by coating the target object with the first rare-earth metal compound through physical vapor deposition (PVD). In this case, there may be a problem in that the lower coating layer is etched during the formation process of the upper coating layer. Therefore, the higher the hardness of the rare-earth metal compound powder forming the upper coating layer or the higher the heat treatment temperature of the rare-earth metal compound powder, the larger the thickness of the lower coating layer, which is preferable. Alternatively, the smaller the nozzle angle during the formation process of the upper coating layer, the higher the etching amount of the lower coating layer. Thus, the thickness of the lower coating layer is preferably increased.

In one embodiment, the lower coating layer preferably has a thickness in a range of 0.1 to 10 μm. When the thickness of the lower coating layer is smaller than 0.1 μm, there may be a problem in that the lower coating layer fails to be partially formed. On the contrary, when the thickness of the lower coating layer exceeds 10 μm, there may be a problem in that process costs are increased, resulting in a decrease in economic feasibility.

Next, the second rare-earth metal compound powder is transferred by supplying a carrier gas [(b)].

In this case, the carrier gas may be supplied at a flow rate of in a range of 15 to 200 standard liters per minute (SLM). The transfer gas may include, for example, an inert gas such as argon.

Subsequently, the upper coating layer containing the second rare-earth metal compound is formed by spraying the second rare-earth metal compound powder onto the lower coating layer formed on the target object. As a result, a plasma-resistant member that includes the target object and the rare-earth metal compound coating film is formed [(O].

The second rare-earth metal compound may include yttria (Y2O3), yttrium fluoride (YF), yttrium oxyfluoride (YOF), yttrium aluminum garnet (YAG), or a mixture thereof. Specifically, the second rare-earth metal compound is preferably yttria (Y2O3).

In this case, the first rare-earth metal compound constituting the lower coating layer preferably has the same components as the second rare-earth metal compound constituting the upper coating layer. The internal stress of the coating film may be minimized by using the same components for both the lower coating layer and the upper coating layer, thereby forming a stable coating film.

Through a heat treatment process according to the present disclosure, the second rare-earth metal compound powder may have a median diameter (D50) in a range of 0.1 to 10 μm. Accordingly, the second rare-earth metal compound powder improves the density, strength, and adhesive strength of the coating film when forming the upper coating layer.

The upper coating layer, containing the second rare-earth metal compound, preferably is a high-density rare earth metal compound having a thickness in a range of 1.0 to 30 μm and a pore content of less than 1.0 vol %.

With the increasing pore content of the upper coating layer, there may be a problem of a decrease in the mechanical strength of the finally formed plasma-resistant coating film. Therefore, the upper coating layer containing the second rare-earth metal compound preferably has low porosity and is dense to obtain the mechanical strength of the plasma-resistant coating film.

However, when forming a coating film using a deposition method in which powders are transferred using a carrier gas and then deposited in a vacuum chamber through a nozzle, the coating film typically has a nanoscale crystal structure including numerous grain boundaries in the coating film. In addition, structural defects such as crack occur due to the fracture energy generated during the deposition, so the coating film typically has poor mechanical properties.

Therefore, in the present disclosure, the first rare-earth metal compound is applied to the lower coating layer through physical vapor deposition (PVD). As a result, when forming the upper coating layer, the lower coating layer may receive the thermal energy and fracture energy applied to the target object, generated from the second rare-earth metal compound powder, thereby minimizing the occurrence of structural defects that may occur in the coating film.

In addition, when the thickness of the upper coating layer is smaller than 1 the thickness itself is excessively small to obtain plasma resistance in a plasma environment. On the contrary, when the thickness of the upper coating layer exceeds 30 μm, the upper coating layer may be delaminated during processing. Furthermore, the excessive use of rare-earth metal compounds may result in economic damage.

In one embodiment of depositing the second rare-earth metal compound powder using the carrier gas to form the upper coating layer, the second rare-earth meal compound powder is loaded into the vacuum chamber. Then, the target object, on which the lower coating layer is formed, is placed in a deposition chamber. In this case, the second rare-earth metal compound powder is supplied from the vacuum chamber and sprayed by being introduced into the deposition chamber with the carrier gas.

As the carrier gas, a condensed gas or an inert gas, such as hydrogen (H2), helium (He), nitrogen (N2), or the like, may be used, in addition to argon (Ar) gas. Due to a pressure difference between the supply device of the second rare-earth metal compound powder and the deposition chamber, both the carrier gas and the second rare-earth metal compound powder are sucked into the deposition chamber while being sprayed onto the target object (base material), on which the lower coating layer is formed, at high speed through the nozzle.

As a result, the second rare-earth metal compound is deposited by the spraying, thus forming the upper coating layer containing the high-density second rare-earth metal compound. A deposition area of the second rare-earth metal compound coating layer is controllable to a desired size by laterally moving the nozzle. In addition, the thickness thereof is determined in proportion to the deposition time, that is, spraying time.

The upper coating layer may be formed by repeatedly laminating the second rare-earth metal compound powder two or more times using the deposition method described above.

In addition, the present disclosure provides a plasma-resistant coating film formed by the method of forming the plasma-resistant coating film. The plasma-resistant coating film has low porosity and exhibits enhanced physical strength.

Hereinafter, the present disclosure will be described in more detail through examples. However, the following embodiments of the present disclosure are disclosed only for illustrative purposes and should not be construed as limiting the present disclosure.

### Comparative Example 1

Deposition proceeded in a vacuum chamber under a low-vacuum condition. The maximum vacuum level was set to 10 mTorr, and a vacuum level during a process formed when supplying a carrier gas was in a range of 0.5 to 5 TOM

Yttria (Y2O3) powder was uniformly supplied from a supply device in a predetermined amount. The yttria (Y2O3) powder supplied ranged from several μm to several tens of μm, and the amount of the powder supplied was managed at a level in a range of 5 to 50 g/min.

The flow of a carrier gas carried away the supplied powder, followed by spraying the powder through a nozzle in the chamber. At this time, the carrier gas was supplied at a flow rate in a range of 15 to 200 SLM, and an inert gas, such as Ar, N2, and He, was used as the carrier gas.

When supplying the carrier gas, a pressure difference between the powder supply device and the vacuum chamber facilitated the carrier gas to be sucked into the vacuum chamber. Due to the gas flow generated at this time, the powder was mixed with the carrier gas and then transferred.

The transferred powder particles were continuously accelerated to be sucked into the vacuum chamber by the pressure difference while the speed when being sprayed through the nozzle reached the speed of sound. The accelerated powder particles collided with a base material. As a result, a yttria coating film having a thickness in a range of 10 μm was formed on the basis of the collision energy generated at this time.

### Examples 1 to 4

Depending on the thickness of a PVD coating layer, a coating material or process conditions of aerosol deposition (AD) coating may vary. When the PVD coating layer has a small thickness, a coating material or process condition with a low etching rate is necessary to be used. In the case of a coating material or process condition with a high etching rate, the PVD coating may be completely etched, so the PVD coating layer needs to have a larger thickness. Therefore, the thickness of the PVD coating layer is required to vary at 0.5, 1.0, 1.5, and 3.0 μm depending on the materials and process conditions of the AD coating.

Examples of a lower layer coated by electron beam evaporation among physical and chemical vapor deposition are as follows.

First, an alumina base material was mirror-polished and then loaded into a coating chamber with the raw material, yttria (Y2O3), to maintain a high-vacuum atmosphere. In this case, the chamber was maintained to have a temperature of 300° C. or lower.

When the chamber reached a high vacuum level, yttria (Y2O3) was irradiated with an electron beam to melt and deposit yttria on the base material. In this case, ion assist was applied to enhance the physical properties of the coating layer.

The coating was performed by adjusting the coating time so that the final coating layer had a thickness of 0.5, 1.0, 1.5, or 3.0 μm.

An AD coating layer was deposited in the same manner as in Comparative Example 1 on each of the PVD coating layers prepared to have the thickness as described above.

TABLE 1

| | PVD coating | | | |
|---|---|---|---|---|
| | thickness | Hardness | Porosity | Presence of cracks |
| | (μm) | (Hv) | (%) | in coating film |
| Comparative | — | 10.271 | 1.12 | ◯ |
| Example 1 | | | | |
| Example 1 | 0.5 | 10.621 | 0.21 | X |
| Example 2 | 1.0 | 10.412 | 0.24 | X |
| Example 3 | 1.5 | 10.324 | 0.23 | X |
| Example 4 | 3.0 | 10.512 | 0.22 | X |

As shown in Table 1, in the plasma-resistant coating films (Examples 1 to 4) according to the present disclosure, the porosity of each AD coating layer, which may result from the structural defects, is reduced, and the physical strength is also enhanced, compared to the coating film (Comparative Example 1) free of the PVD lower coating layer.

Specific aspects of the present disclosure have been described in detail above, and those skilled in the art will appreciate that these specific aspects are only preferred embodiments, and the scope of the present disclosure is not limited thereby. Thus, the substantial scope of the present disclosure will be defined by the appended claims and their equivalents.

What is claimed is:

1. A method of forming a plasma-resistant coating film, the method comprising:
(a) forming a lower coating layer on a target object by depositing a first rare-earth metal compound powder through a physical vapor deposition (PVD) process;
(b) transferring a second rare-earth metal compound powder; and
(c) forming an upper coating layer by spraying the transferred second rare-earth metal compound powder onto the lower coating layer formed in the (a) forming,
wherein each of the first rare-earth metal compound powder and the second rare-earth metal compound powder is selected from the group consisting of yttria (Y2O3), yttrium oxyfluoride (YOF), and yttrium aluminum garnet (YAG), and
the first rare-earth metal compound powder has the same components as the second rare-earth metal compound powder.

2. The method of claim 1, wherein the physical vapor deposition (PVD) process is one selected from among thermal deposition, electron beam evaporation, and sputtering.

3. The method of claim 1, wherein the lower coating layer has a thickness in a range of 0.1 to 10 μm.

4. The method of claim 1, wherein the second rare-earth metal compound powder has a median diameter (D50) in a range of 0.1 to 10 μm.

5. The method of claim 1, wherein the upper coating layer has a thickness in a range of 1 to 30 μm.

6. A plasma-resistant coating film formed by the method of claim 1.
